(19) United States
(12) Patent Application Publication
(10) Pub. No.: US 2022/0198819 A1
(43) Pub. Date: Jun. 23, 2022

(54) ELECTRONIC DEVICE

(71) Applicant: Egis Technology Inc., Hsinchu City (TW)

(72) Inventors: Chun-Ching Tseng, Hsinchu City (TW); Kuan-Yi Lin, Hsinchu City (TW)

(73) Assignee: Egis Technology Inc., Hsinchu City (TW)

(21) Appl. No.: 17/601,442

(22) PCT Filed: Dec. 2, 2019
(86) PCT No.: PCT/CN2019/122322

§ 371 Date: Oct. 5, 2021

Related U.S. Application Data
(60) Provisional application No. 62/863,270, filed on Jun. 19, 2019.

(51) Int. Cl. G06V 40/13; H01L 27/32

(52) U.S. Cl. CPC G06V 40/1318; H01L 27/3234

(57) ABSTRACT

An electronic device for sensing a fingerprint image of a finger, and including a light-emitting element, a sensing module, and a controller, is provided. The light-emitting element includes multiple light-emitting pixels arranged in an array, and has a fingerprint sensing region. The sensing module is disposed underneath the fingerprint sensing region to receive an irradiation beam that reaches the sensing module after being reflected by the finger, so as to generate the fingerprint image. The controller is electrically connected to the light-emitting element. The fingerprint sensing region is divided into at least a first region and a second region from its center to its periphery. When the light-emitting element provides the irradiation beam to irradiate the finger, the controller controls a light emission time of the light-emitting pixels in the first region to be shorter than a light emission time of the light-emitting pixels in the second region.

### BACKGROUND

### Technical Field

This disclosure relates to an electronic device, and in particular to an electronic device capable of sensing a fingerprint.

### Description of Related Art

With continuous evolution and improvement of electronic technologies and manufacturing technologies, informative electronic products are also constantly innovated. Computers, mobile phones, cameras and other electronic products have become essential tools for people in the modern day. In addition, fingerprint sensing devices also have to be integrated into current smart mobile devices, so as to enhance security of the smart mobile devices and to support more smart functions.

Currently, a user may press a finger on a display of a mobile phone to perform fingerprint sensing. However, during the sensing process, the light intensity sensed by sensing pixels in a sensing module near the periphery is often lower than the light intensity sensed by the sensing pixels in the sensing module near the center, causing the intensity of an optical signal obtained by the sensing module to have a variation, which affects accuracy of the fingerprint sensing. Therefore, in a current solution, a back-end software is often used to correct the intensity of the signal, but the corrected image still has issues, such as noise is amplified and causes a loss of details. Therefore, how to allow a fingerprint sensing module to be capable of sensing uniformed intensity of an optical signal remains a challenge for those skilled in the art.

### SUMMARY

This disclosure provides an electronic apparatus, which has a good fingerprint sensing function.

An embodiment of the disclosure provides an electronic device that is configured to sense a fingerprint image of a finger, and includes a light-emitting element, a sensing module, and a controller. The light-emitting element includes multiple light-emitting pixels arranged in an array, has a fingerprint sensing region, and is configured to provide an irradiation beam to the finger. The sensing module is disposed underneath the fingerprint sensing region, and is configured to receive the irradiation beam that reaches the sensing module after being reflected by the finger, so as to generate the fingerprint image. The controller is electrically connected to the light-emitting element, so as to control light emission of the light-emitting element. The fingerprint sensing region is divided into at least a first region and a second region from its center to its periphery. When the light-emitting element provides the irradiation beam to irradiate the finger, the controller controls a light emission time of the light-emitting pixels in the first region to be shorter than a light emission time of the light-emitting pixels in the second region.

In the electronic device according to an embodiment of the disclosure, when the light-emitting element provides the irradiation beam to irradiate the finger, the controller controls the light emission time of the light-emitting pixels in the fingerprint sensing region from the center to the periphery to show an increasing trend.

In the electronic device according to an embodiment of the disclosure, the light-emitting element is a transparent display panel.

In the electronic device according to an embodiment of the disclosure, the transparent display panel is an organic light-emitting diode display panel.

In the electronic device according to an embodiment of the disclosure, the sensing module includes an image sensor.

In the electronic device according to the embodiment of the disclosure, the light emission time of the light-emitting pixels in the first region is controlled by the controller to be shorter than the light emission time of the light-emitting pixels in the second region, therefore the light energy sensed by the center of the sensing module is close to the light energy sensed by the edge of the sensing module per unit time. In this way, the image sensed by the sensing module can have uniformed brightness, while preventing the situation in which the middle is bright while the edge is dark.

### BRIEF DESCRIPTION OF THE DRAWINGS

The accompanying drawings are included for further understanding of the disclosure, and the drawings are incorporated into this specification and constitute a part of this specification. The drawings illustrate the embodiments of the disclosure, and together with the descriptions serve to explain the principles of the disclosure.

FIG. 1A is a schematic cross-sectional view of an electronic device according to an embodiment of the disclosure.

FIG. 1B is a schematic top view of a fingerprint sensing region of a light-emitting element in FIG. 1A.

FIG. 2 is a light intensity distribution diagram of the irradiation beam emitted by the light-emitting element of the electronic device in FIG. 1A.

FIG. 3 is a light intensity distribution diagram of the image detected by the sensing module when the light emission time of all of the light-emitting pixels in the fingerprint sensing region is the same.

FIG. 4 is a light emission time distribution diagram of the light-emitting pixels at various positions in the fingerprint sensing region of the electronic device in FIG. 1A.

FIG. 5 is a distribution diagram of the light energy detected by the sensing module of the electronic device in FIG. 1A per unit time.

### DESCRIPTION OF THE EMBODIMENTS

Reference will now be made in detail to exemplary embodiments of the disclosure, and examples of the exemplary embodiments are illustrated in the accompanying drawings. Whenever possible, the same reference numerals are used in the drawings and descriptions to indicate the same or similar parts.

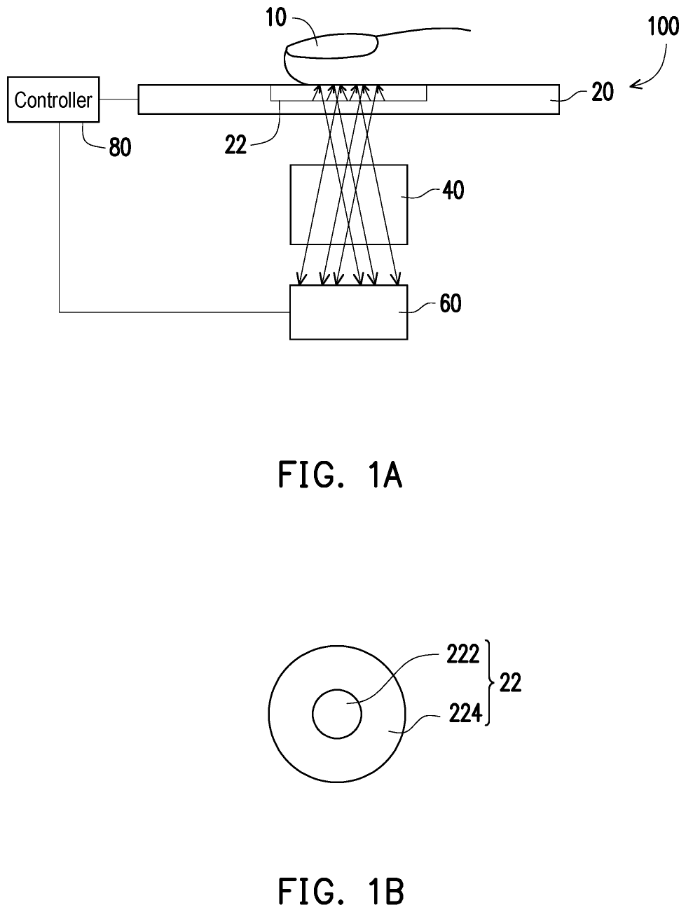

FIG. 1A is a schematic cross-sectional view of an electronic device according to an embodiment of the disclosure, and FIG. 1B is a schematic top view of a fingerprint sensing region of a light-emitting element in FIG. 1A. With reference to FIGS. 1A and 1B concurrently, an electronic device 100 of the embodiment is configured to sense a fingerprint image of a finger 10 of a user, and the electronic device 100 includes a light-emitting element 20, a sensing module 60, and a controller 80. The light-emitting element 20 includes multiple light-emitting pixels arranged in an array, and the light-emitting element 20 has a fingerprint sensing region 22, which is configured to provide an irradiation beam to the finger 10 of the user, and the user may place the finger 10 on the fingerprint sensing region 22 to perform fingerprint sensing.

In the embodiment, the light-emitting element 20 is, for example, a display panel (such as a transparent display panel), a touch display panel (such as a transparent touch display panel), or a combination of the above and a finger pressure plate. For example, the light-emitting element 20 is, for example, an organic light-emitting diode display panel (OLED display panel), but the disclosure is not limited thereto. Alternatively, the light-emitting element 20 may be a touch display panel, such as an OLED display panel having multiple touch electrodes. The multiple touch electrodes may be formed on an outer surface of the OLED display panel or be embedded in the OLED display panel, and the multiple touch electrodes may perform touch detection by self-capacitance or mutual capacitance. Alternatively, the light-emitting element 20 may be a combination of a finger pressure plate and a display panel or a combination of a finger pressure plate and a touch display panel.

In the embodiment, the electronic device 100 may further include an optical module 40, which is disposed between the fingerprint sensing region 22 and the sensing module 60, so as to guide an irradiation beam reflected by the finger 10 to the sensing module 60 to form the fingerprint image. The optical module 40 is, for example, a lens assembly that has a collimator structure, and/or includes a micro-lens layer and/or a pin-holes layer. In the embodiment, the optical module 40 is, for example, a lens assembly, including a combination of one or more optical lenses with refractive power. For example, various combinations of non-planar lenses such as a biconcave lens, a biconvex lens, a meniscus lens, a convex-concave lens, a plano-convex lens, and a plano-concave lens. However, the disclosure does not limit the form and the type of the optical module 40. For example, the optical module 40 is composed of two lenses, but in other embodiments, it may be composed of three lenses or four lenses, and the disclosure is not limited thereto.

In the embodiment, the sensing module 60 is disposed underneath the fingerprint sensing region 22, and is configured to receive the irradiation beam that reaches the sensing module after being reflected by the finger 10, so as to generate a fingerprint image. The sensing module 60 includes an image sensor, and the image sensor includes multiple sensing pixels, and the multiple sensing pixels are arranged in a sensing array. Each of the sensing pixels may include at least one photodiode, but the disclosure is not limited thereto. When fingerprint sensing is being performed, the user places the finger 10 close to or on the fingerprint sensing region 22 of the light-emitting element 20, and the light-emitting element 20 emits the irradiation beam to irradiate the finger 10, which is sequentially transmitted through the light-emitting element 20 and the optical module 40 to be transmitted to the sensing module 60 to perform fingerprint sensing after being reflected by the finger.

In addition, the electronic device 100 also includes a controller 80, which is electrically connected to the light-emitting element 20, so as to control light emission of the light-emitting element 20. The fingerprint sensing region 22 may be divided into at least a first region 222 and a second region 224 from its center to its periphery, and when the light-emitting element 20 provides the irradiation beam to irradiate the finger 10, the controller 80 controls a light emission time of the light-emitting pixels in the first region 222 to be shorter than a light emission time of the light-emitting pixels in the second region 224. In this way, light energy sensed by a center of the sensing module 60 is close to light energy sensed by an edge of the sensing module 60 per unit time (such as time of a single-time fingerprint sensing), enabling the image sensed by the sensing module to have a relatively uniformed brightness, while preventing a situation in which the image sensed by the prior art has a bright middle but a dark edge. In an embodiment, when the light-emitting element 20 provides the irradiation beam to irradiate the finger 10, the controller 80 controls the light emission time of the light-emitting pixels in the fingerprint sensing region 22 from the center to the periphery to show an increasing trend, which may further enable the brightness of the image sensed by the sensing module 60 to be uniformed across the entire surface, so as to further improve quality of the fingerprint image, thereby effectively improving a success rate and accuracy of fingerprint recognition.

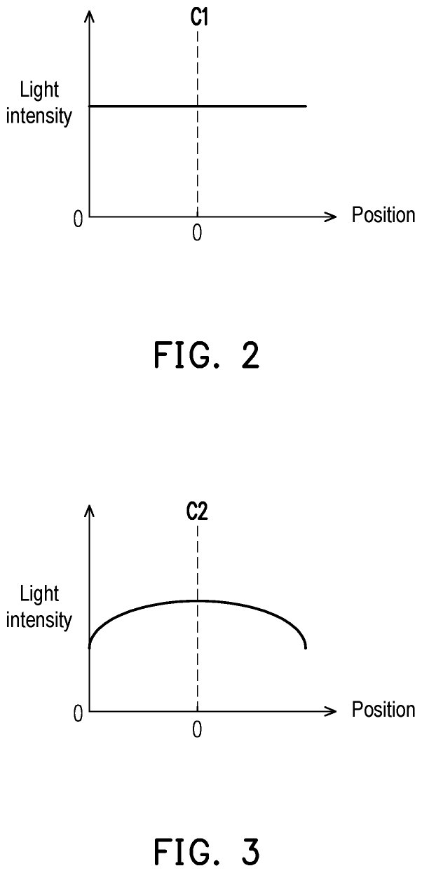

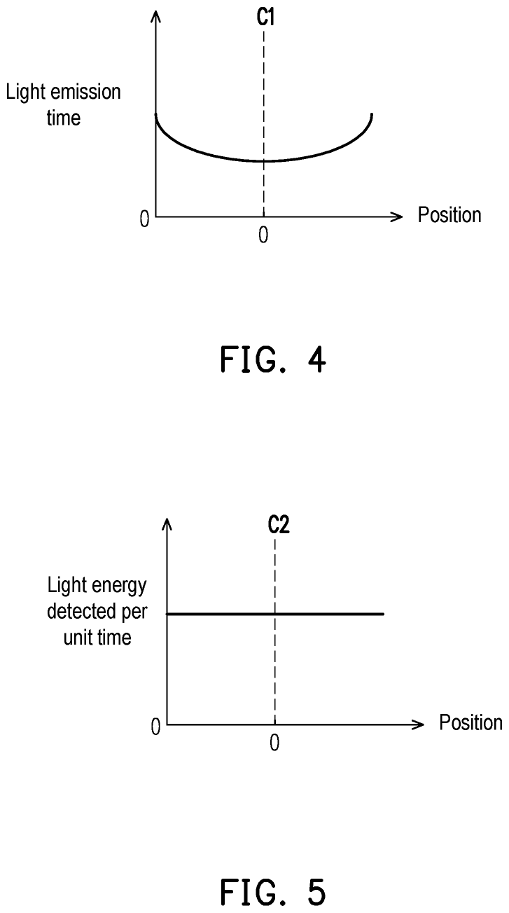

FIG. 2 is a light intensity distribution diagram of the irradiation beam emitted by the light-emitting element of the electronic device in FIG. 1A. With reference to FIGS. 1A, 1B and 2 concurrently, when the user places the finger 10 or an object on the fingerprint sensing region 22 of the light-emitting element 20 to perform fingerprint recognition sensing, the fingerprint sensing region 22 of the light-emitting element 20 emits the irradiation beam to irradiate the finger 10 or the object. At this time, light intensity in the fingerprint sensing region 22 is, for example, uniformed. When the light emission time of all the light-emitting pixels in the fingerprint sensing region 22 is the same, the light intensity of the image detected by the sensing module 60 is as shown in FIG. 3, in which there is a situation where the middle is bright and the edge is dark. However, in the embodiment, the controller 80 controls the light emission time of the light-emitting pixels in the fingerprint sensing region 22 from the center to the periphery to show an increasing trend, as shown in FIG. 4. The light energy detected by the sensing pixels at each position on the sensing module 60 per unit time is uniformed, as shown in FIG. 5, and the light energy detected per unit time is reflected in the brightness of the image sensed by the sensing module 60. In other words, the sensing module 60 may sense an image having uniformed brightness through the controller 80 performing the above-mentioned control. A center line Cl in FIGS. 2 and 4 corresponds to a center position of the fingerprint sensing region 22, that is, at a position in the figure that is 0, while a center line C2 in FIGS. 3 and 5 corresponds to a center position of the sensing module 60, that is, at a position in the figure that is 0.

In the embodiment, the electronic device 100 may be a handheld electronic device, such as a smart phone, a tablet computer, and other handheld electronic devices, and the light-emitting element 20 may serve as a display to show a frame to be viewed by the user when fingerprint recognition is not performed. During the fingerprint recognition, the light-emitting element 20 may emit light from the entire surface or only in the fingerprint sensing region 22, so as to generate the irradiation beam to illuminate the finger 10.

In an embodiment, the controller 80 is, for example, a central processing unit (CPU), a microprocessor, a digital signal processor (DSP), a programmable controller, a programmable logic device (PLD), or other similar devices, or a combination of these devices, but the disclosure is not limited thereto. In addition, in an embodiment, functions of the controller 80 may be implemented as multiple program codes. The program codes are stored in a memory, and the program codes are executed by the controller 80. Alternatively, in an embodiment, the functions of the controller 80 may be implemented as one or more circuits. The disclosure does not limit usage of software or hardware to implement the functions of the controller 80.

In addition, in the embodiment, the controller 80 may also be electrically connected to the sensing module 60, so as to synchronize the light emission time of the light-emitting element 20 with the sensing time of the sensing module 60.

In summary, in the electronic device according to the embodiment of the disclosure, the light emission time of the light-emitting pixels in the first region is controlled by the controller to be shorter than the light emission time of the light-emitting pixels in the second region, therefore the light energy sensed by the center of the sensing module is close to the light energy sensed by the edge of the sensing module per unit time. In this way, the image sensed by the sensing module can have uniformed brightness, while preventing the situation in which the middle is bright while the edge is dark.

Finally, it should be noted that the above embodiments are only illustrations of the technical solutions of the disclosure, and are not meant to limit the disclosure. Although the disclosure has been described in detail with reference to the foregoing embodiments, those of ordinary skill in the art should understand that modifications may be made to the technical solutions described in the foregoing embodiments, or equivalent replacements of some or all of the technical features may be done, however, these modifications or replacements do not cause the essence of the corresponding technical solutions to deviate from the scope of the technical solutions according to the embodiments of the disclosure.

What is claimed is:

1. An electronic apparatus, configured to sense a fingerprint image of a finger, comprising:
a light-emitting element, comprising a plurality of light-emitting pixels arranged in an array, wherein the light-emitting element has a fingerprint sensing region, and is configured to provide an irradiation beam to the finger;
a sensing module, disposed underneath the fingerprint sensing region, and is configured to receive the irradiation beam that reaches the sensing module after being reflected by the finger, so as to generate the fingerprint image; and
a controller, electrically connected to the light-emitting element to control light emission of the light-emitting element, wherein the fingerprint sensing region is divided into at least a first region and a second region from its center to its periphery, and when the light-emitting element provides the irradiation beam to irradiate the finger, the controller controls a light emission time of light-emitting pixels in the first region to be shorter than a light emission time of light-emitting pixels in the second region.

2. The electronic device according to claim 1, wherein when the light-emitting element provides the irradiation beam to irradiate the finger, the controller controls a light emission time of light-emitting pixels in the fingerprint sensing region from the center to the periphery to show an increasing trend.

3. The electronic device according to claim 1, wherein the light-emitting element is a transparent display panel.

4. The electronic device according to claim 3, wherein the transparent display panel is an organic light-emitting diode display panel.

5. The electronic device according to claim 1, wherein the sensing module comprises an image sensor.
